(19) United States
(12) Patent Application Publication
(10) Pub. No.: US 2021/0398002 A1
(43) Pub. Date: Dec. 23, 2021

(54) PARALLEL PROXY MODEL BASED MACHINE LEARNING METHOD FOR OIL RESERVOIR PRODUCTION

(71) Applicant: China University of Petroleum (East China), Shandong (CN)

(72) Inventors: Kai ZHANG, Shandong (CN); Liming ZHANG, Shandong (CN); Chuanjin YAO, Shandong (CN); Yongfei YANG, Shandong (CN); Zhixue SUN, Shandong (CN); Jian WANG, Shandong (CN); Chao ZHONG, Shandong (CN); Xiaoming XUE, Shandong (CN); Guodong CHEN, Shandong (CN)

(21) Appl. No.: 17/407,708

(22) Filed: Aug. 20, 2021

(30) Foreign Application Priority Data
Jun. 22, 2020 (CN) 202010572648.1

(51) Int. Cl. G06N 7/00; G06N 20/00; G06F 30/27; G06Q 10/04; G06Q 10/06; G06Q 50/02; G06F 16/23; E21B 43/16

(52) U.S. Cl. CPC G06N 7/00; G06N 20/00; G06F 30/27; G06Q 10/04; E21B 2200/22; G06Q 50/02; G06F 16/2379; E21B 43/16; E21B 2200/20; G06Q 10/067

(57) ABSTRACT

The present disclosure relates to a parallel proxy model based machine learning method for oil reservoir production. With the proposed method, multiple optimized candidate solutions can be obtained within an iteration, and then a matrix laboratory (e.g., MATLAB) is used to call numerical simulation software Eclipse in parallel to conduct actual evaluation on the candidate solutions simultaneously, so that optimization time of complex problems can be greatly reduced. With the method of the present disclosure, the efficiency of solving an oilfield production optimization problem can be speeded up to a greater extent than in the art, and the final optimization effect can be improved. Moreover, the method of the present disclosure may further be used for well pattern optimization, history matching, and so on, apart from adjusting schedules of the producers and injectors in the oilfield.

### CROSS REFERENCE TO RELATED APPLICATION(S)

This patent application claims the benefit and priority of Chinese Patent Application No. 202010572648.1 filed on Jun. 22, 2020, the disclosure of which is incorporated by reference herein in its entirety as part of the present application.

### TECHNICAL FIELD

The present disclosure belongs to the technical field of petroleum, relates to a method for solving an oil reservoir production optimization problem, and particularly to a parallel proxy model based machine learning method for oil reservoir production.

### BACKGROUND ART

As one of the essential parts of oilfield management, oil reservoir production optimization aims to obtain maximum economic benefits by adjusting an oilfield production schedule, such as parameters of a water well and an oil well. The commonly used index is a net present value (NPV). Nowadays, oil reservoir numerical simulation is often used to simulate a production and development process of the whole oil reservoir, so as to guide a production plan of an oilfield. However, the oil reservoir numerical simulation is faced with two main challenges. First, it is computationally expensive; for a complex oil reservoir, it takes several hours or even several days to conduct a numerical simulation, and thousands of iterations are required to obtain an optimized production plan; as a result, plan formulation is time-consuming. Second, an oilfield possibly includes dozens or even hundreds of producers or water injectors, and there exists a plurality of variables for each of the wells, which means that oilfield production optimization will be faced with a high-dimensional problem.

A proxy model assisted evolutionary algorithm is a machine learning method that is capable of speeding the optimization effectively and has become a research hotspot around the world. An evolutionary algorithm is a mature global optimization method with high robustness and wide applicability, capable of optimizing a black-box problem that cannot be solved by a traditional gradient algorithm. The evolutionary algorithm, as an optimization method of global random search, needs more iterations than the gradient algorithm, and cannot be directly used to solve the problem of expensive computation. A proxy model is a mathematical model that is constructed by using certain sample points and has less computational load but is close to an original calculation or experimental result. The proxy model assisted evolutionary algorithm combines the evolutionary algorithm and the proxy model, and replaces actual expensive simulation or experiments with the proxy model having less computational load. That is, the proxy model is used to evaluate points to be selected generated by the evolutionary algorithm, and the best individual in a population is selected for actual evaluation, thus remarkably reducing optimization time. The common proxy models include a Kriging model, a radial basis function, support vector regression, etc.

There are two key parts in the proxy model assisted evolutionary algorithm, one of which is to use sample points to build a rational proxy model, and the other of which is to use the proxy model to screen out the optimal point from candidate points generated by the evolutionary algorithm, and to make an actual evaluation and update the proxy model. This process is called serial dynamic sampling. Although the proxy model assisted evolutionary algorithm can speed the oilfield production optimization, it is still time-consuming Only one candidate point can be selected for actual simulation evaluation in each iteration of the serial dynamic sampling, so parallel calculation resources cannot be utilized, even if they exist. Therefore, parallel dynamic sampling can be used to improve the optimization speed, but existing parallel sampling methods, such as Constant Liar and Kriging Believer, cannot be used in a high-dimensional condition, and thus cannot be used to solve a production optimization problem of the oilfield.

### SUMMARY

In view of the above, the present disclosure provides a parallel proxy model based machine learning method for oil reservoir production, which can make full use of computational resources and improve optimization efficiency. More specifically, to solve the problems of excessive computation load, long calculation time, and high dimension when oil reservoir numerical simulation is used for production optimization design, the present disclosure provides a parallel proxy model based machine learning method for oil reservoir production, which may make full use of computation resources and improve optimization efficiency.

A parallel proxy model based machine learning method for oil reservoir production can include the following steps:

(1) determining an optimization variable and an initial design space, initializing the number of optimization iteration, i.e. setting FEs as 0, and mathematically describing production optimization of an oilfield as:

$$\begin{matrix} Find x = [ {x}_{1} , {x}_{2} , ⋯ , {x}_{m} ] & ( 1 ) \\ Max f ( x ) & ( 2 ) \\ s . t . {x}_{i}^{l o w} \leq {x}_{i} \leq {x}_{i}^{up} ( i = 1 , 2 , … , m ) & ( 3 ) \\ J ( u , v ) = {\sum }_{n = 1}^{{N}_{t}} \{ \frac{Δ {t}_{n}}{{( 1 + b )}^{\frac{{t}_{n}}{365}}} [ {\sum }_{j = 1}^{P} ( {r}_{o} \cdot {q}_{o , j}^{n} - {c}_{w} \cdot {q}_{w , j}^{n} ) - {\sum }_{j = 1}^{I} ( {c}_{wi} \cdot {q}_{wi , j}^{n} ) ] \} & ( 4 )\end{matrix}$$

where x is a production optimization variable; m is a dimension of the optimization variable; f (x) is an objective function of production optimization problem of an oilfield; xᵢ^{low} and xᵢ^{up} are a lower boundary and an upper boundary of the optimization variable respectively; J(u,v) represents a net present value (NPV), in unit of USD; Nₜ is a total simulation step length; tₙ is time of an n-th simulation step length, in unit of D; b is an annual attenuation rate; q_{o,j}ⁿ, q_{w,j}ⁿ and q_{wi,j}ⁿ represent daily average oil production and daily average water production of a j-th producing well in an n-th step, and a daily water injection rate of an i-th water injection well in the n-th step respectively, in unit of STB/D; rₒ and c_{w} are a price of each unit of oil, cost of treating each unit of waste water and cost of injecting a cubic meter of water respectively, in unit of USD/STB; and P and I are the number of producers and the number of water injectors respectively;

(2) conducting sampling in the initial design space to obtain a sampling point set S=[x¹; x²; . . . x^{N}], using a matrix laboratory (e.g., MATLAB) to modify a production schedule of the oilfield according to the sampling point set, calling an oil reservoir numerical simulation software Eclipse in parallel to conducting actual numerical simulation on a modified production schedule, to obtain a response set Y=[y¹; y²; . . . y^{N}], and using a sampling point and values of a corresponding response set to construct a sample database DB;

(3) selecting q candidate points for actual simulation from the sample database DB with a parallel sampling based on mapping;

(4) using the matrix laboratory (e.g., MATLAB) to call the numerical simulation software Eclipse in parallel to calculating response values of the q candidate points for actual simulation; adding the q candidate points for actual simulation and the corresponding response values into the sample database DB and updating the sampling point set S and the response set Y; increasing the number of optimization iterations FEs by 1; and

(5) determining whether a stopping criterion is met, stopping iteration and outputting an optimal solution if the number of optimization iteration reaches a set number, and otherwise returning to step (3).

Furthermore, the production optimization variable may include an injection rate of injectors, the bottom-hole pressure of producers, the production rate of producers, the well locations, etc.

Furthermore, the parallel sampling strategy based on mapping in step (3) may include specific implementation steps shown as follows:

1) creating a temporary sampling point set S^{temp}, letting S^{temp}=S; and creating a temporary response set Y^{temp}, letting Y^{temp}=Y;

2) using a differential evolution algorithm to conduct crossover and mutation on the temporary sampling point set S^{temp}, to obtain a high-dimensional candidate population C^{temp}=[c¹; c²; . . . c^{N}];

3) projecting S^{temp} and C^{temp} simultaneously to obtain corresponding populations S̅^{temp} temp and C̅^{temp} in a low-dimensional space through Sammon mapping;

4) using S̅^{temp} and Y^{temp} as training samples to construct a Kriging proxy model;

5) using the proxy model obtained and a lower confidence bound criterion to calculate a lower confidence bound value of each point in C̅^{temp}, and selecting a point c̅^{best} with a maximum lower confidence bound value among the points; and

6) finding an individual c^{best} corresponding to c̅^{best} in the high-dimensional candidate population C^{temp}, setting a response value of c^{best} as L, updating the temporary sampling point set S^{temp} and the temporary response set Y^{temp}, where letting S^{temp}=[S^{temp}; c^{best}] and Y^{temp}=[Y^{temp}; L], recording c^{best}, and returning to step 2) until q points are obtained.

Furthermore, L=min(Y^{temp}); the crossover and mutation may include the following specific implementation steps:

$$\begin{matrix}{v}^{i} = {x}^{r 1} + F ( {x}^{r 2} - {x}^{r 3} ) & ( 5 ) \\ {c}_{j} = \{ \begin{matrix}{v}_{j} & if rand ( 0 , 1 ) \leq CR & \\ {x}_{j} & otherwise & \end{matrix} & ( 6 )\end{matrix}$$

where vⁱ is a result generated after the mutation of an i-th individual in the temporary sampling point set S^{temp}; F is a mutation operator, and F∈(0,2]; x^{r1}, x^{r2} and x^{r3} are three completely different individuals randomly selected from the temporary sampling point set S^{temp}; CR is a crossover operator, and CR∈(0,1]; and cⱼ, vⱼ and xⱼ are j-th dimensions of a population after crossover, a population after mutation and an original population.

Furthermore, step 5) may include the following specific implementation steps:

LCB(x)=\hat{y}(x)−wŝ(x) (7)

where LCB(x) is a lower confidence bound value at x, ŷ(x) is a response value of x predicted by the Kriging proxy model, and ŝ(x) is a mean square error of x calculated by the Kriging proxy model.

Compared with the prior art, the present disclosure has the following advantages that multiple high-quality candidate solutions can be obtained within an iteration, and then the matrix laboratory (e.g., MATLAB) may be used to call the numerical simulation software Eclipse in parallel to evaluate the candidate solutions at the same time, so that optimization time for complex problems can be reduced greatly.

### BRIEF DESCRIPTION OF THE DRAWINGS

FIG. 1 is an overall design flowchart according to the present disclosure;

FIG. 2 is a flowchart of aparallel sampling strategy based on mapping according to the present disclosure;

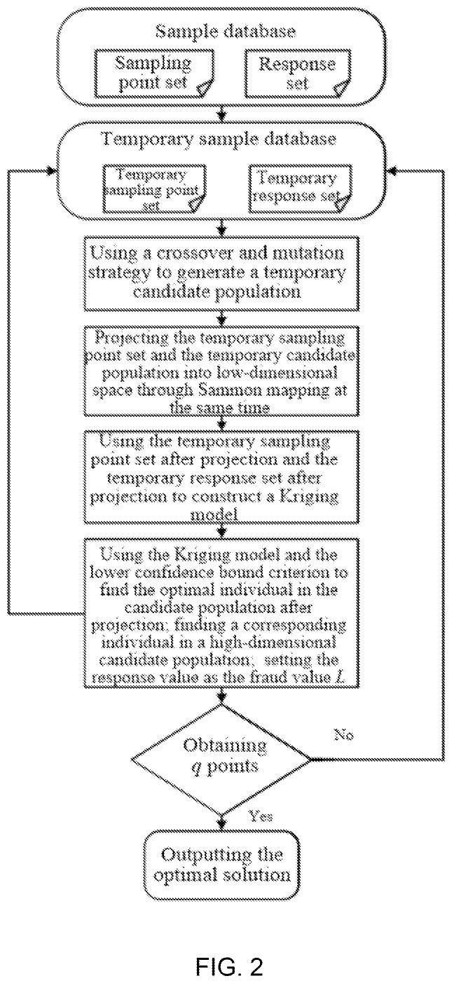

FIG. 3 is a graph depicting the convergence of a net present value obtained through optimization according to the present disclosure;

FIG. 4a is a graph of oilfield production total obtained through optimization as a function of time according to the present disclosure;

FIG. 4b is a graph of field water production total obtained through optimization as a function of time according to the present disclosure;

FIG. 4c is a graph of oilfield water injection total obtained through optimization as a function of time according to the present disclosure; and

FIG. 4d is a graph of oilfield water cut obtained through optimization as a function of time according to the present disclosure.

### DETAILED DESCRIPTION OF THE EMBODIMENTS

To make the object, the technical solution, and the advantages of the present disclosure more clear, the present disclosure is further described in detail with reference to following embodiments. It should be understood that the specific embodiments described herein are merely used to explain the present disclosure, but not to limit the present disclosure. That is, the described embodiments are only part but not all of the embodiments of the present disclosure.

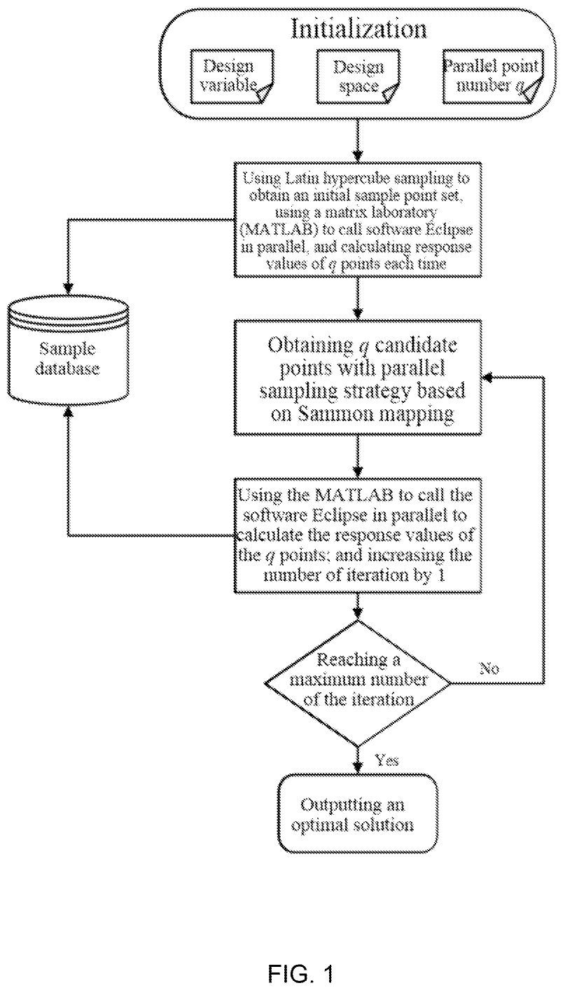

With reference to FIG. 1, a parallel proxy model based machine learning method for oil reservoir production includes the following steps:

1) determining an optimization variable and an initial design space, initializing the iteration number, i.e., setting FEs as 0, taking a net present value (NPV) as an optimization objective, and mathematically describing production optimization of an oilfield as Formulas (8)-(11):

$$\begin{matrix} Find x = [ {x}_{1} , {x}_{2} , ⋯ , {x}_{m} ] & ( 8 ) \\ Max f ( x ) = J ( x ) & ( 9 ) \\ s . t . {x}_{i}^{l o w} \leq {x}_{i} \leq {x}_{i}^{up} ( i = 1 , 2 , … , m ) & ( 10 ) \\ J ( u , v ) = {\sum }_{n = 1}^{{N}_{t}} \{ \frac{Δ {t}_{n}}{{( 1 + b )}^{\frac{{t}_{n}}{365}}} [ {\sum }_{j = 1}^{P} ( {r}_{o} \cdot {q}_{o , j}^{n} - {c}_{w} \cdot {q}_{w , j}^{n} ) - {\sum }_{j = 1}^{I} ( {c}_{wi} \cdot {q}_{wi , j}^{n} ) ] \} & ( 11 )\end{matrix}$$

where x is a production optimization variable, which may include a water injection rate of injectors, bottomhole pressure of producers, production rate of producers, and the like; m is the dimension of the optimization variable, where water injection rates of 8 injectors are optimized, optimization time is 10 years, and thus the dimension m=8×10=80; J(x) represents a net present value (NPV), in units of USD, and which may represent revenue of oilfield development and production over a certain period of time; xᵢ^{low} and xᵢ^{up} are a lower boundary and an upper boundary of the optimization variable respectively; Nₜ is a total simulation step length; tₙ is time of an n-th simulation step length, in unit of D; b is an annual attenuation rate; q_{o,j}ⁿ, q_{w,j}ⁿ and q_{wi,j}ⁿ represent daily average oil production and daily average water production of a j-th producer in an n-th step, and a daily water injection rate of an i-th injectors in the n-th step respectively, in units of STB/D; rₒ and c_{w} are a price of each unit of oil, cost of treating each unit of waste water and cost of injecting a unit of water respectively, in unit of USD/STB; and P and I are the number of producers and the number of injectors respectively;

2) conducting initial sampling in the initial design space by Latin hypercube sampling (LHS) to obtain an initial sampling point set S=[x¹; x²; . . . x^{N}], the number of initial sample points is 100, that is, N=100; using, according to the sampling point set, a matrix laboratory (e.g., MATLAB) to modify production schedules of the oilfield, and calling the numerical simulation software Eclipse in parallel to conduct actual numerical simulation on a modified production schedules to obtain a response set Y=[y¹; y²; . . . y^{N}], and using a sampling points and corresponding response values to construct a sample database DB;

3) creating a temporary sampling point set S^{temp} andl etting S^{temp}=S; creating a temporary response set Y^{temp} and letting Y^{temp}=Y;

4) using a differential evolution algorithm to conduct crossover and mutation on the temporary sampling point set S^{temp}, to obtain a high-dimensional candidate population C^{temp}=[c¹; c²; . . . c^{N}], where a crossover and mutation processes are shown in Formulas (5) and (6); and a minimum of current response values serves as a fraud value L, that is, letting L=min(Y);

5) projecting S^{temp} and C^{temp} into low-dimensional space R^{d} by a Sammon mapping method at the same time, where d may represent a dimension, generally under the condition that d=0.1m (i.e., d=8), and obtaining corresponding populations S̅^{temp} and C̅^{temp} in the low-dimensional space; the number of individuals in S̅^{temp} and C̅^{temp} is consistent with that of S^{temp} and C^{temp}, and individuals in high-dimensional space and low-dimensional space are in one-to-one correspondence;

6) constructing a Kriging proxy model by using S̅^{temp} and Y^{temp} as training samples;

7) using the Kriging proxy model obtained to calculate predicted values and mean square errors of all individuals in C̅^{temp}, and to calculate lower confidence bound (LCB) values of all points according to a lower confidence bound criterion; selecting a point with a maximum LCB value of the points, denoted as c̅^{best};

8) finding an individual c^{best} corresponding to c̅^{best} in the high-dimensional candidate population C^{temp}, and setting a response value of the c^{best} as the fraud value L; updating the temporary populations S^{temp} and Y^{temp}, letting S^{temp}=[S^{temp};c^{best}] and Y^{temp}=[Y^{temp}; L], and recording the c^{best}; returning to the step 4) until q points are obtained, where q=15;

9) using the matrix laboratory (e.g., MATLAB) to call the numerical simulation software Eclipse in parallel, to calculate response values of the q points, and adding the q points and their response values into the sample database DB; updating S and Y, and increasing the iteration number by 1, that is FEs=FEs+1; and

10) determining whether a stopping criterion is met, stopping iteration and outputting an optimal solution under the condition that the number of optimizations reaches a set number, and otherwise returning to step 3).

The advantages of the present disclosure may be further explained by an oil reservoir numerical simulation test as follows:

1. Oil reservoir numerical simulation test conditions

The whole oilfield may contain 12 wells, where the number of water injectors is 8, and the number of producers may be 4. Daily water injection rates of the 8 water injectors are optimization variables, and a lower boundary and an upper boundary may be 0 STB/D and 500 STB/D respectively; the producers may undertake constant bottom-hole pressure production at 5,757.5 psi; a price of crude oil, the cost for treating the waste water, and cost for injecting water are 20, 1 and 3 USD/STB respectively; the annual attenuation rate is 0%; and production time is 3,600 days, which may be divided into 10 steps in average, each step may last for 360 days.

2. Simulation Results

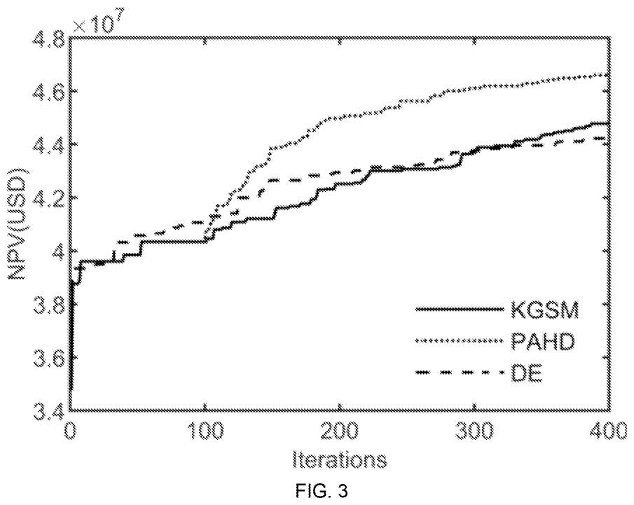

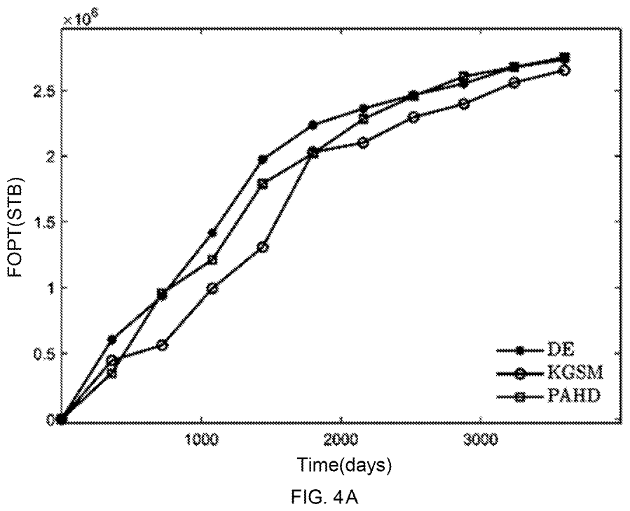

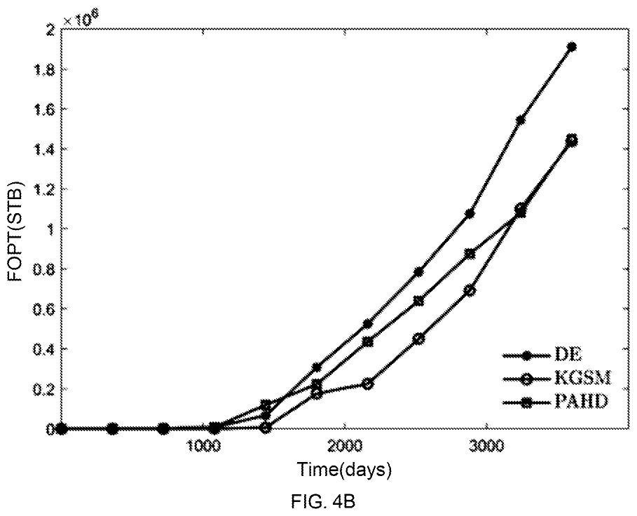

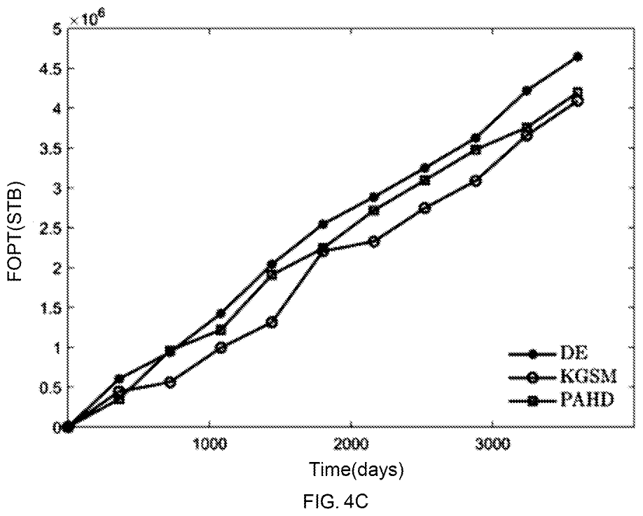

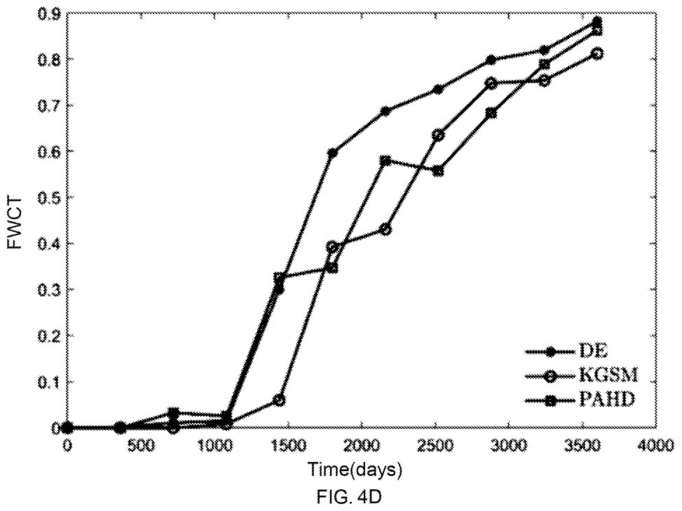

FIG. 3 is a convergence curves of three methods, which may be the method (PAHD) provided herein, differential evolution (DE), and the method based on a Kriging model and Sammon mapping (KGSM). To avoid contingency, each algorithm is tested independently 5 times. FIGS. 4a-4d are comparison charts of other important indexes of the oilfield produced according to the best well control as a function of time, which include oilfield oil production total (FOPT), oilfield water injection total (FWIT), oilfield water production total (FWPT), and oilfield water cut (FWCT).

FIG. 3 shows average values of the 5 times of tests of the three different algorithms. It can be observed from FIG. 3 that the effect obtained through the proposed method may be better than that obtained through the DE and the KGSM. It may be seen from FIGS. 4a-4d that when production optimization is conducted according to the proposed method, the oilfield oil production total may be similar to that obtained through the DE, both of which may be higher than that obtained through the KGSM, but the oilfield water injection total, the oilfield water production total and the oilfield water cut of the proposed method are all lower than those obtained through the DE, thus realizing the effect of “increasing oil and controlling water.”

With the method of the present disclosure, the efficiency of solving an oilfield production optimization problem can be speeded up to a greater extent than is possible in the art, and the final optimization effect can be improved. Moreover, the method of the present disclosure may further be used for well pattern optimization, history matching, and so on, apart from adjusting production schedules of the producers and injectors in the oilfield.

Of course, the above descriptions are not intended to limit the present disclosure, the present disclosure is not limited to the above examples, and variations, modifications, additions, or substitutions which may be made by those skilled in the art within the essential scope of the present disclosure fall within the protective scope of the present disclosure.

What is claimed is:

1. A parallel proxy model based machine learning method for oil reservoir production, wherein the method comprises:
(1) determining an optimization variable and an initial design space, initializing the iteration number, i.e, setting FEs as 0, and mathematically describing production optimization of an oilfield as:
$$\begin{matrix} Find x = [ {x}_{1} , {x}_{2} , ⋯ , {x}_{m} ] & ( 1 ) \\ Max f ( x ) & ( 2 ) \\ s . t . {x}_{i}^{l o w} \leq {x}_{i} \leq {x}_{i}^{up} ( i = 1 , 2 , … , m ) & ( 3 ) \\ J ( u , v ) = {\sum }_{n = 1}^{{N}_{t}} \{ \frac{Δ {t}_{n}}{{( 1 + b )}^{\frac{{t}_{n}}{365}}} [ {\sum }_{j = 1}^{P} ( {r}_{o} \cdot {q}_{o , j}^{n} - {c}_{w} \cdot {q}_{w , j}^{n} ) - {\sum }_{j = 1}^{I} ( {c}_{wi} \cdot {q}_{wi , j}^{n} ) ] \} & ( 4 )\end{matrix}$$
where x is a production optimization variable; m is a dimension of the optimization variable; f(x) is an objective function of a production optimization problem; xᵢ^{low} and xᵢ^{up} are a lower boundary and an upper boundary of the optimization variable respectively; J(u,v) represents a net present value (NPV), in unit of USD; Nₜ is a total simulation step length; tₙ is time of an n-th simulation step length, in unit of D; b is an annual attenuation rate; q_{o,j}ⁿ, q_{w,j}ⁿ and q_{wi,j}ⁿ represent daily average oil production and daily average water production of a j-th producing well in an n-th step, and a daily water injection rate of an i-th water injection well in the n-th step respectively, in unit of STB/D; rₒ and c_{w} are a price of each unit of oil, cost of treating each unit of waste water and cost of injecting a cubic meter of water respectively, in unit of USD/STB; and P and I are the number of producers and the number of water injectors respectively;
(2) conducting sampling in the initial design space to obtain a sampling point set S=[x¹; x²; . . . x^{N}], using a matrix laboratory to modify a production schedule of the oilfield according to the sampling point set, calling numerical simulation software Eclipse in parallel to conduct actual numerical simulation on a modified production schedule to obtain a response set Y=[y¹; y²; . . . y^{N}], and using a sampling point and values of a corresponding response set to construct a sample database DB;
(3) selecting q candidate points for actual simulation from the sample database DB with a parallel sampling based on mapping;
(4) using the matrix laboratory to call the numerical simulation software Eclipse in parallel to calculate response values of the q candidate points for actual simulation; adding the q candidate points for actual simulation and the corresponding response values into the sample database DB and updating the sampling point set S and the response set Y; increasing the number of optimization iterations FEs by 1; and
(5) determining whether a stopping criterion is met, stopping iteration and outputting an optimal solution if the number of optimization iteration reaches a set number, and otherwise returning to step (3).

2. The parallel proxy model based machine learning method for oil reservoir production according to claim 1, wherein the production optimization variables are selected from: an injection rate of injectors, a bottom-hole pressure of producers, a production rate of producers, and well locations.

3. The parallel proxy model based machine learning method for oil reservoir production according to claim 1, wherein the parallel sampling comprises:
1) creating a temporary sampling point set S^{temp}, letting S^{temp}=S; and creating a temporary response set Y^{temp}, letting Y^{temp}=Y;
2) using a differential evolution algorithm to conduct crossover and mutation on the temporary sampling point set S^{temp}, to obtain a high-dimensional candidate population C^{temp}=[c¹; c²; . . . c^{N}];
3) projecting S^{temp} and C^{temp} simultaneously to obtain corresponding populations S̅^{temp} and C̅^{temp} in a low-dimensional space through Sammon mapping;
4) constructing a Kriging proxy model by using S̅^{temp} and Y^{temp} as training samples;
5) using the proxy model obtained and a lower confidence bound criterion to calculate a lower confidence bound value of each point in C̅^{temp}, and selecting a point c̅^{best} with a maximum lower confidence bound value among the points; and
6) finding an individual c^{best} corresponding to c̅^{best} in the high-dimensional candidate population C^{temp}, setting a response value of c^{best} as L, updating the temporary sampling point set S^{temp} and the temporary response set Y^{temp}, where letting S^{temp}=[S^{temp}; c^{best}] and Y^{temp}=[Y^{temp}; L], recording c^{best}, and returning to step 2) until q points are obtained.

4. The parallel proxy model based machine learning method for oil reservoir production according to claim 3, wherein letting L=min(Y^{temp}) and the crossover and mutation comprises the following steps:
$$\begin{matrix}{v}^{i} = {x}^{r 1} + F ( {x}^{r 2} - {x}^{r 3} ) & ( 5 ) \\ {c}_{j} = \{ \begin{matrix}{v}_{j} & if rand ( 0 , 1 ) \leq CR & \\ {x}_{j} & otherwise & \end{matrix} & ( 6 )\end{matrix}$$
where v¹ is a result generated after the mutation of an i-th individual in the temporary sampling point set S^{temp}; F is a mutation operator, and F∈(0,2]; x^{r1}, x^{r2} and x^{r3} are three different individuals randomly selected from the temporary sampling point set S^{temp}; CR is a crossover operator, and CR∈(0,1]; and cⱼ, vⱼ and xⱼ are the j-th dimensions of a population after crossover, a population after mutation and an original population.

5. The parallel proxy model based machine learning method for oil reservoir production according to claim 3, wherein the using the proxy model comprises:
LCB(x)=ŷ(x)−wŝ(x) (7)
where LCB(x) is a lower confidence bound value at x, ŷ(x) is a response value of x predicted by means of the Kriging proxy model, and ŝ(x) is a mean square error of x calculated by means of the Kriging proxy model.

6. The parallel proxy model based machine learning method for oil reservoir production according to claim 1, wherein the matrix laboratory is MATLAB.
